(19) United States
(12) Patent Application Publication
(10) Pub. No.: US 2009/0263052 A1
(43) Pub. Date: Oct. 22, 2009

(54) DUAL SLIDING APPARATUS

(75) Inventor: Han Sang LEE, Seoul (KR)

Correspondence Address: ROBERTS MLOTKOWSKI SAFRAN & COLE, P.C.;Intellectual Property Department, P.O. Box 10064, MCLEAN, VA, 22102-8064, US

(73) Assignees: Han Sang LEE, Seoul (KR); P & TEL INC., Seoul (KR)

(21) Appl. No.: 12/107,397

(22) Filed: Apr. 22, 2008

(51) Int. Cl. F16C 33/10; H05K 5/00; F16C 29/02

(52) U.S. Cl. 384/13; 384/26

(57) ABSTRACT

Disclosed is a dual sliding opening/closing apparatus adapted for various electronic devices of a sliding opening/closing type (e.g. cellular phones, PDAs, laptop computers) to guarantee the stability of sliding movements. The apparatus is installed between first and second bodies so that the second body can slide between first and second positions on the first body. The apparatus includes a plurality of sliding opening/closing modules having a sliding member installed on the first body in a sliding direction of the second body and a guide rail member movably coupled to the sliding member and installed on the second body. The sliding opening/closing modules are installed along the direction of perpendicular to the sliding direction.

### BACKGROUND OF THE INVENTION

1. Field of the Invention

The present invention relates to a sliding opening/closing apparatus, and more particularly to a dual sliding opening/closing apparatus adapted for comparatively wide electronic devices of a sliding opening/closing type (e.g. cellular phones, PDAs, laptop computers) to guarantee the stability of sliding movements.

2. Description of the Prior Art

In general, sliding-type electronic devices include a body, a cover slidably installed on the body, and a sliding opening/closing apparatus installed between the body and the cover so that the cover can slide between a first position, in which it is closed on the body, and a second position, in which it is opened from the body.

Particularly, wide electronic devices, e.g. sliding-type PDAs or laptops, conventionally have a single sliding mechanism installed in the sliding direction. This has a problem in that, when the cover is slid upward or downward relative to the body, the cover may vibrate in the leftward/rightward direction, i.e. in a direction perpendicular to the sliding direction, and degrade the operational stability.

Such leftward/rightward vibration during sliding movements deforms sliding components or heavily wears them, shortening their service life. In order to prevent such deformation and wear, the thickness and size of components must be larger than is necessary. This is an obstacle to making the electronic devices compact and slim.

### SUMMARY OF THE INVENTION

Therefore, the present invention has been made in view of the above-mentioned problems, and the present invention provides a dual sliding opening/closing apparatus having a pair of sliding modules mounted side by side along the width of a wide electronic device to improve the operational stability in the upward/downward sliding direction.

In accordance with an aspect of the present invention, there is provided a dual sliding opening/closing apparatus installed between first and second bodies so that the second body can slide between first and second positions on the first body, the apparatus including a plurality of sliding opening/closing modules having a sliding member installed on the first body in a sliding direction of the second body and a guide rail member movably coupled to the sliding member and installed on the second body, the sliding opening/closing modules being installed at two or more positions which are located along a direction perpendicular to the sliding direction so that, when the second body slides, the second body is prevented from vibrating in a leftward/rightward direction perpendicular to the sliding direction.

According to another aspect of the present invention, there is provided a dual sliding opening/closing apparatus installed between first and second bodies so that the second body can slide between first and second positions on the first body, the apparatus including a pair of sliding members having engaging portions formed on both lateral peripheries in a sliding direction of the second body, the sliding members being installed on left and right sides of the first body which are located along a direction perpendicular to the sliding direction; and a pair of guide rail members having rail portions on both lateral peripheries to engage with the engaging portions of the sliding members and slide, the guide rail members being installed in positions on the second body corresponding to the pair of sliding members, wherein lubricating members are mounted on the engaging portions of the sliding members to reduce friction occurring in portions contacting the rail portions of the guide rail members and improve lubrication.

According to another aspect of the present invention, there is provided a dual sliding opening/closing apparatus installed between first and second bodies so that the second body can slide between first and second positions on the first body, the apparatus including a pair of sliding members having engaging portions formed on both lateral peripheries in a sliding direction of the second body, the sliding members being installed on left and right sides of the first body which are located along a direction perpendicular to the sliding direction; and a guide rail member provided with slot rail portions, the engaging portions of the pair of sliding members being fitted to the slot rail portions so as to slide, and installed on the second body, wherein lubricating members are mounted on the engaging portions of the sliding members to reduce friction occurring in portions contacting the slot rail portions of the guide rail members and improve lubrication.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is an exploded perspective view of a dual sliding opening/closing apparatus according to a first embodiment of the present invention;

FIG. 2 is an exploded perspective view of the apparatus shown in FIG. 1 when viewed in the opposite direction;

FIG. 3 is an assembled perspective view of the apparatus shown in FIG. 1;

FIG. 4 is a sectional view of the apparatus shown in FIG. 3 taken along line A-A;

FIGS. 5 and 6 illustrate the operation of the apparatus shown in FIG. 14;

FIG. 7 is an enlarged perspective view of a link-type spring of the apparatus shown in FIG. 1;

FIG. 8 is an exploded perspective view of internal construction of the spring shown in FIG. 7;

FIG. 9 is a perspective view of a torsion spring as an alternative to the link-type spring shown in FIG. 1;

FIG. 10 is a perspective view of a dual sliding opening/closing apparatus according to a second embodiment of the present invention;

FIG. 11 is an exploded perspective of the apparatus shown in FIG. 10 when viewed in the opposite direction;

FIG. 12 is an exploded perspective view of a dual sliding opening/closing apparatus according to a third embodiment of the present invention;

FIG. 13 is an exploded perspective view of the apparatus shown in FIG. 12 when viewed in the opposite direction;

FIG. 14 is an assembled perspective view of the apparatus according to the third embodiment of the present invention;

FIG. 15 is a sectional view of the apparatus shown in FIG. 14 taken along line B-B;

FIG. 16 is an exploded perspective view of a dual sliding opening/closing apparatus according to a fourth embodiment of the present invention;

FIG. 17 is an exploded perspective view of the apparatus shown in FIG. 16 when viewed in the opposite direction;

FIG. 18 is an exploded perspective view of a dual sliding opening/closing apparatus according to a fifth embodiment of the present invention;

FIG. 19 is an assembled sectional view of the apparatus shown in FIG. 18; and

FIG. 20 is a sectional view of a dual sliding opening/closing apparatus according to a sixth embodiment of the present invention.

### DETAILED DESCRIPTION OF THE PREFERRED EMBODIMENTS

Hereinafter, exemplary embodiments of the present invention will be described with reference to the accompanying drawings.

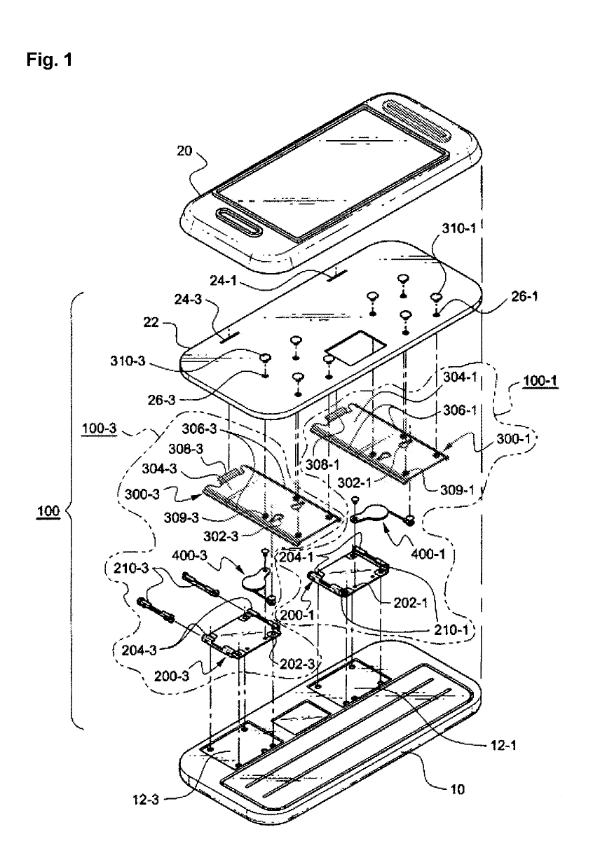

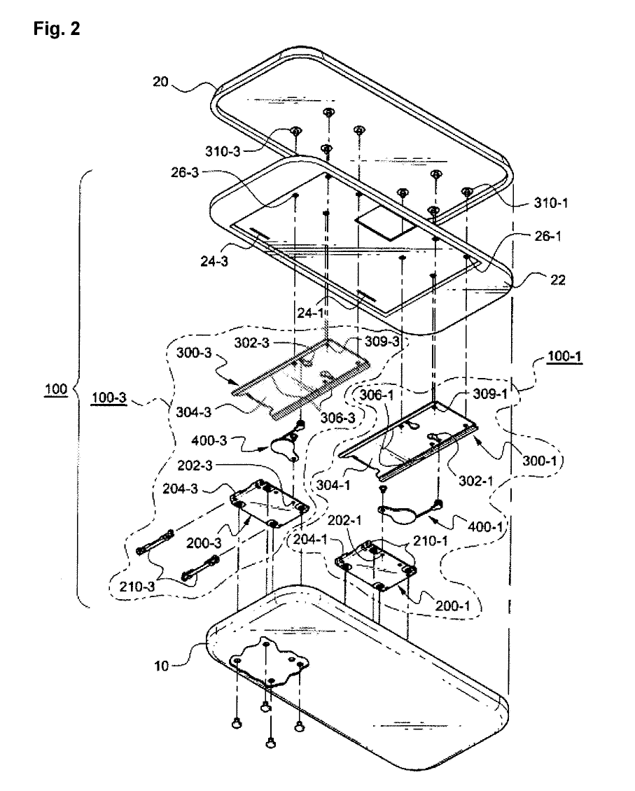

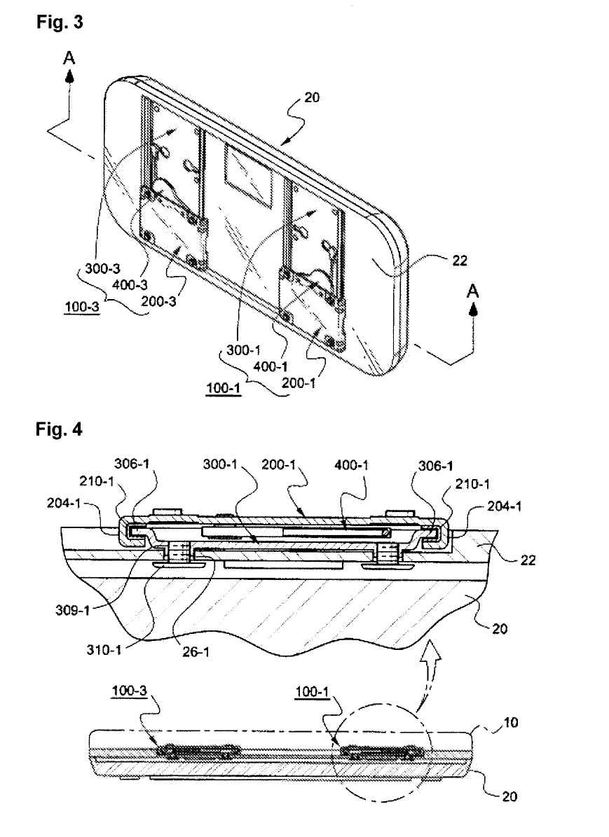

FIG. 1 is an exploded perspective view of a dual sliding opening/closing apparatus according to a first embodiment of the present invention. FIG. 2 is an exploded perspective view of the apparatus shown in FIG. 1 when viewed in the opposite direction. FIG. 3 is an assembled perspective view of the apparatus shown in FIG. 1. FIG. 4 is a sectional view of the apparatus shown in FIG. 3 taken along line A-A.

As shown, the dual sliding opening/closing apparatus 100 according to the present invention is installed between a first body 101, which constitutes the body of a wide electronic device (e.g. a cellular phone, a PDA, or a laptop computer) and a second body 20, which is coupled to the body and acts as a cover, so that the second body 20 can slide between first and second positions on the first body 10 to be closed on the body or opened from it. If necessary, the first or second body 10 or 20 may include some components of the apparatus 100.

The first body 10 preferably has a pair of square recesses 12-1 and 12-3 on the left and right sides so that the dual sliding opening/closing apparatus 100 can be installed thereon. This minimizes or eliminates the gap between other portions of the first and second bodies 10 and 20. In other words, this is a type of design consideration for making the electronic device, to which the opening/closing apparatus 100 is applied, compact and slim to the greatest extent. Alternatively, the pair of square recesses 12-1 and 12-3 on the left and right sides may be connected to each other to form a single square recess.

The dual sliding opening/closing apparatus 100 according to the present invention has a pair of sliding opening/closing modules 100-1 and 100-3 on the left and right sides. The sliding opening/closing modules 100-1 and 100-3 are installed on the left and right sides while being parallel with and spaced from each other along the width of the electronic device. At least two sliding opening/closing modules are installed on the left and right sides of the electronic device, respectively. Considering how wide the electronic device is, a number of sliding opening/closing modules may be additionally arranged in the middle along the width, or at the same distance from one another along the width. According to the present invention, at least one pair of sliding opening/closing modules are positioned to face each other on the left and right sides of the electronic device.

Respective sliding opening/closing modules 100-1 and 100-3 include sliding members 200-1 and 200-3 seated on and fixed to the first body 10, and guide rail members 300-1 and 300-3 slidably coupled to the sliding members 200-1 and 200-3, respectively. Particularly, a pair of sliding members 200-1 and 200-3 are seated on and fixed to a pair of square recesses 12-1 and 12-3 of the first body 10. The fixation is based on gluing, welding, or bolting, for example. The sliding members 200-1 and 200-3 are preferably bolted inside the first body 10. The apparatus 100 has springs 400-1 and 400-3 installed between the sliding members 200-1 and 200-3 and the guide rail members 300-1 and 300-3 to multiply the sliding operation force of the sliding members 200-1 and 200-3 and the guide rail members 300-1 and 300-3. The springs 400-1 and 400-3 are compressed until approximately half the sliding distance between the sliding members 200-1 and 200-3 and the guide rail members 300-1 and 300-3 is reached. After half the sliding distance is exceeded, the compression force is turned into restoration force, which facilitates the sliding. As such, the springs 400-1 and 400-3 help the user to conduct a sliding movement to the destination with little force. Preferably, a pair of link-type springs are used as the springs 400-1 and 400-3. More preferably, a pair of link-type springs 400-1 and 400-3 are installed to face each other. One ends of the two link-type springs 400-1 and 400-3 are rotatably connected to holes 202-1 and 202-3 of the sliding members 200-1 and 200-3, respectively, and the other ends of the link-type springs 400-1 and 400-3 are fitted into and rotatably connected to fitting holes 302-1 and 302-3 of the guide rail members 300-1 and 300-3, respectively. The link-type springs 400-1 and 400-3 are installed between the first and second bodies 10 and 20 of the electronic device to push the sliding members 200-1 and 200-3 and the guide rail members 300-1 and 300-3 to the first position, in which the second body 20 is closed, or to the second position, in which the second body 20 is opened. More particularly, the link-type springs 400-1 and 400-3 are compressed and apply force toward the first position until approximately half the total sliding distance is traveled. After half the sliding distance is exceeded, the compressed springs are restored and apply force toward the second position.

Each sliding member 200-1 and 200-3 has a pair of engaging portions 204-1 and 204-3 formed along both lateral peripheries to face each other. The engaging portions 204-1 and 204-3 are preferably formed on both lateral surfaces in a concave shape (i.e. U-shape) while extending continuously from the lower end to the upper end. If necessary, the engaging portions 204-1 and 204-3 may span near the upper and lower ends only. The guide rail members 300-1 and 300-3 are positioned inside the pair of engaging portions 204-1 and 204-3 facing each other, and the left and right edges of the guide rail members 300-1 and 300-3 engage with and couple to the left and right engaging portions 204-1 and 204-3. The guide rail members 300-1 and 300-3 have rail portions 306-1 and 306-3 formed on left and right lateral peripheries and bent from rail bodies 304-1 and 304-3 toward the sliding members 200-1 and 200-3 to fit into the engaging portions 204-1 and 204-3, respectively. Since both edges of the guide rail members 300-1 and 300-3 are bent toward the sliding members 200-1 and 200-3, a space is created between the guide rail members 300-1 and 300-3 and the sliding members 200-1 and 200-3, which are slidably coupled to each other. The above-mentioned link-type springs 400-1 and 400-3 are arranged and coupled in the intermediate space. Particularly, lubricating members 210-1 and 210-3 are mounted inside the engaging portions 204-1 and 204-3 to reduce friction with regard to the rail portions 306-1 and 306-3 and guarantee smooth sliding movements. The lubricating members 210-1 and 210-3 are made of a material having both resistance to wear and lubrication properties, preferably a plastic-based material. The lubricating members 210-1 and 210-3 have a shape corresponding to that of the engaging portions 204-1 and 204-3. Preferably, the lubricating members 210-1 and 210-3 are integrated in an insert type during fabrication of the sliding members 200-1 and 200-3. The guide rail members 300-1 and 300-3 have fitting holes 302-1 and 302-3 formed on the rail bodies 304-1 and 304-3 so that one ends of the link-type springs 400-1 and 400-3 are fitted and coupled to the fitting holes 302-1 and 302-3, and a pair of rail portions 306-1 and 306-3 bent from both ends of the rail bodies 304-1 and 304-3. The rail portions 306-1 and 306-3 slidably engage with the engaging portions 204-1 and 204-3 of the sliding members 200-1 and 200-3. The guide rail members 300-1 and 300-3 are coupled to the rear plate 22 of the second body 20. For the sake of this coupling, the rear plate 22 of the second body 20 has a pair of coupling recesses 24-1 and 24-3 formed thereon, and the rail bodies 304-1 and 304-3 of the guide rail members 300-1 and 300-3 have corresponding engaging ledges 308-1 and 308-3 formed thereon while being bent. The rear plate 22 and the guide rail members 300-1 and 300-3 have a number of first and second bolt holes 26-1, 26-3, 309-1, and 309-3 formed on corresponding portions, respectively. Therefore, the engaging ledges 308-1 and 308-3 of the guide rail members 300-1 and 300-3 are fitted into the coupling recesses 24-1 and 24-3 of the rear plate 22, and then bolts 310-1 and 310-3 are fastened to the first and second bolt holes 26-1, 26-3, 309-1, and 309-3 of the rear plate 22 and the guide rail members 300-1 and 300-3 to couple both members. Instead of the bolting-type coupling, the guide rail members 300-1 and 300-3 and the rear plate 22 may also be coupled by gluing or welding. Therefore, the exemplified structure necessary for bolting may be modified depending on the type of coupling the guide rail members 300-1 and 300-3 and the rear plate 22. It can be easily understood by those skilled in the art that the rear plate 22 is coupled to the second body 20 by various coupling methods, including bolting, gluing, etc.

The sliding members 200-1 and 200-3 and the guide rail members 300-1 and 300-3 are preferably made of a thin metal plate. If necessary, the sliding members 200-1 and 200-3 may be molded by using plastic.

The coupling order will now be described. The lubricating members 210-1 and 210-3 are inserted into and coupled to the engaging portions 204-1 and 204-3 of the sliding members 200-1 and 200-3. It is also possible to integrally mold the lubricating members 210-1 and 210-3 in an insert type when the sliding members 200-1 and 200-3 are manufactured. The rail portions 306-1 and 306-3 of the guide rail members 300-1 and 300-3 are fitted to the left and right engaging portions 204-1 and 204-3 of the sliding members 200-1 and 200-3 to couple the sliding members 200-1 and 200-3 and the guide rail members 300-1 and 300-3. One ends of the link-type springs 400-1 and 400-3 are rotatably coupled to the holes 202-1 and 202-3 of the sliding members 200-1 and 200-3, and the other ends are fitted and rotatably coupled to the fitting holes 302-1 and 302-3 of the guide rail members 300-1 and 300-3. The link-type springs 400-1 and 400-3 are coupled between the sliding members 200-1 and 200-3 and the guide rail members 300-1 and 300-3 in this manner to assemble the pair of sliding opening/closing modules 100-1 and 100-3.

The pair of sliding opening/closing modules 100-1 and 100-3 assembled in this manner are coupled to left and right sides between the first and second bodies 10 and 20, which then can slide relative to each other. More particularly, the sliding members 200-1 and 200-3 of the sliding opening/closing modules 100-1 and 100-3 are fixed to the left and right square recesses 12-1 and 12-3 of the first body 10, respectively, and the guide rail members 300-1 and 300-3 are fixed to the rear plate 22 of the second body 20. Then, the sliding opening/closing apparatus 100 including the pair of sliding opening/closing modules 100-1 and 100-3 is completely coupled between the first and second bodies 10 and 20.

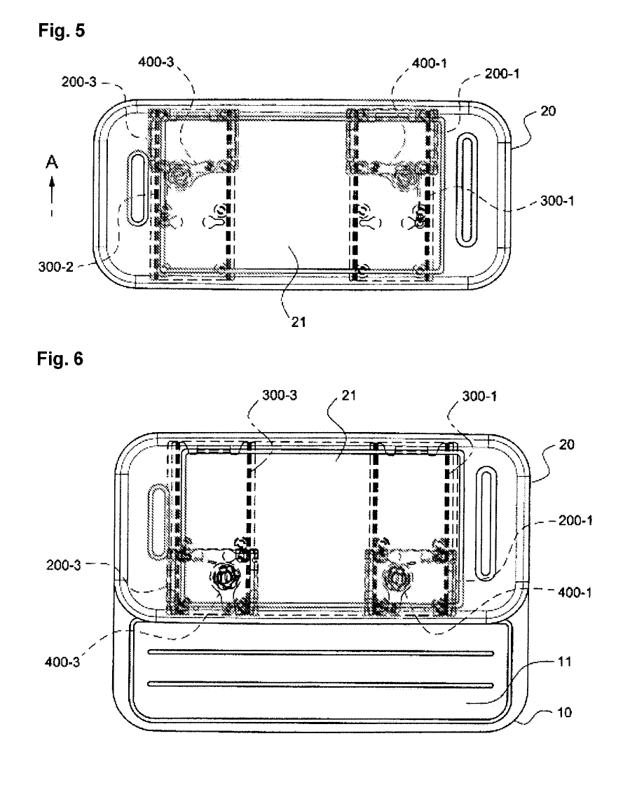

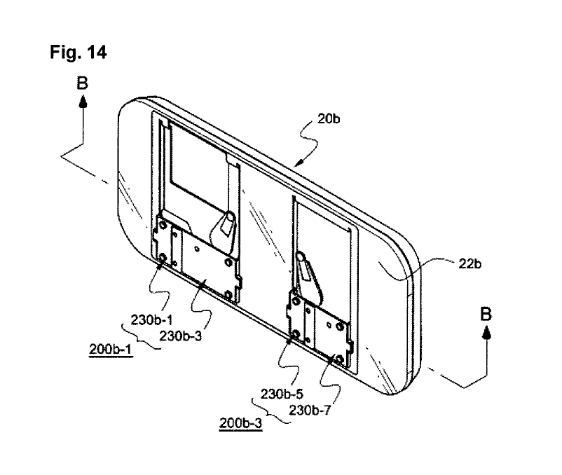

FIGS. 5 and 6 illustrate the operation of the apparatus shown in FIG. 14. Particularly, FIG. 5 shows the cover when closed, and FIG. 6 shows the cover when opened. The operation of the apparatus will be described in detail with reference to these drawings, as well as FIG. 14.

The second body (cover) 20, which is closed on the first body (main body) 10, is pushed upward along arrow A as shown in FIG. 5. Then, the pair of guide rail members 300-1 and 300-3 on the left and right sides, which have been coupled to the pair of sliding members 200-1 and 200-3 on the left and right sides, slide away from them. As such, the left and right sides of the second body 20 are stably supported and guided by the left and right sliding opening/closing modules including the sliding members 200-1 and 200-3 and the guide rail members 300-1 and 300-3, which are slidably coupled to each other, so that the second body 20 moves stably. Particularly, the link-type springs 400-1 and 400-3 are compressed until the second body 20 travels approximately half the sliding operation section, and the compression force is turned into restoration force after half the section has been traveled. Then, the restoration force from the springs 400-1 and 400-3 is added to the sliding force of the second body 20 and moves it to the final position. As such, the pair of sliding opening/closing modules of the apparatus according to the present invention are installed on the left and right sides to prevent the wide electronic device from vibrating in the leftward/rightward direction during sliding and guarantee stable sliding. In addition, the springs 400-1 and 400-3 are compressed and restored during the sliding and provide force necessary to guarantee smooth and easy sliding.

After the second body 20 is fully opened from the first body 10 through the above-mentioned operation, the key input unit 11 (e.g. keypad or keyboard) of the first body 10 is exposed together with the display unit 21 of the second body 20 and gets ready for input operations, as shown in FIG. 6.

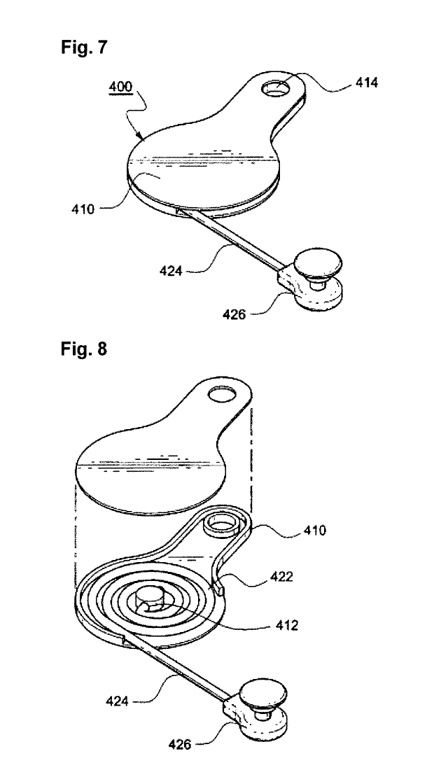

FIG. 7 is an enlarged perspective view of a link-type spring of the apparatus shown in FIG. 1. FIG. 8 is an exploded perspective view of internal construction of the spring shown in FIG. 7.

The link-type spring 400 mounted between the sliding member and the guide rail member to multiply the sliding force according to the present invention, as shown in FIGS. 7 and 8, includes a rice scoop-shaped link plate 410 having a coupling hole 412 formed on one side, and a spring portion 420 having a coil portion 422 fixed to the coupling hole 412 so that a leg portion 424 extends from the coil portion 422 and protrudes from the link plate 410. The link plate 410 is preferably shaped to surround and support both lateral surfaces of the coil portion 422. The link-type spring 400 having this construction has a fixing hole 414 formed farthest from the coupling hole 412 of the link plate 410 so that it can be rotatably coupled to the sliding member. One end of the leg 424 is configured as a mounting end 426 to be fitted and rotatably coupled to the fitting hole of the guide rail member.

As such, the link-type spring 400 has a coil portion 422 mounted inside the link plate 410 to undergo compression and restoration and multiply the sliding force so that both lateral surfaces are supported to prevent twisting during operations. This minimizes distortion or damage of the spring. The spring has a planar structure resulting from the link plate 410, and can be easily installed in the narrow space between the guide rail member and the sliding member. This improves the convenience of assembly.

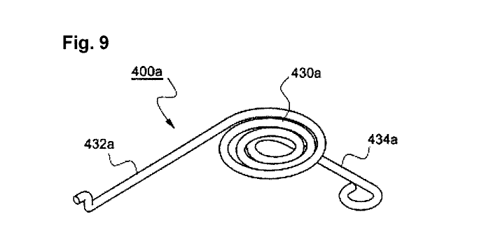

FIG. 9 is a perspective view of a torsion spring as an alternative to the link-type spring shown in FIG. 1. The link-type spring having the above-mentioned construction may be replaced with a torsion spring 400a, which has two leg portions 432a and 432b extending from the central coil portion 430a. As in the case of the link-type spring, one end (the leg portion on one side) of the torsion spring 400a is rotatably coupled to the sliding member, and the other end (the leg portion on the other side) is rotatably coupled to the guide rail member.

Besides the link-type spring and the torsion spring exemplified in FIGS. 7-9, other types of springs (e.g. coil springs, leaf springs) may also be used.

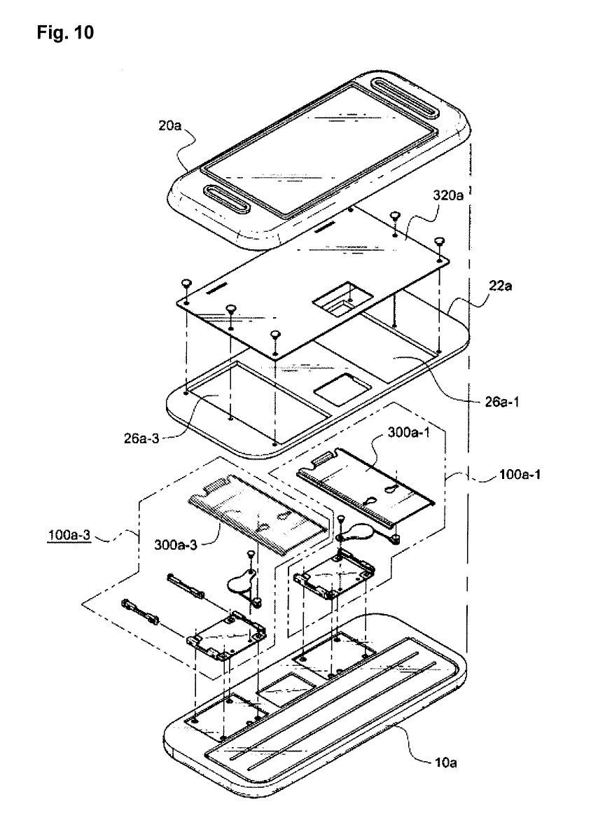

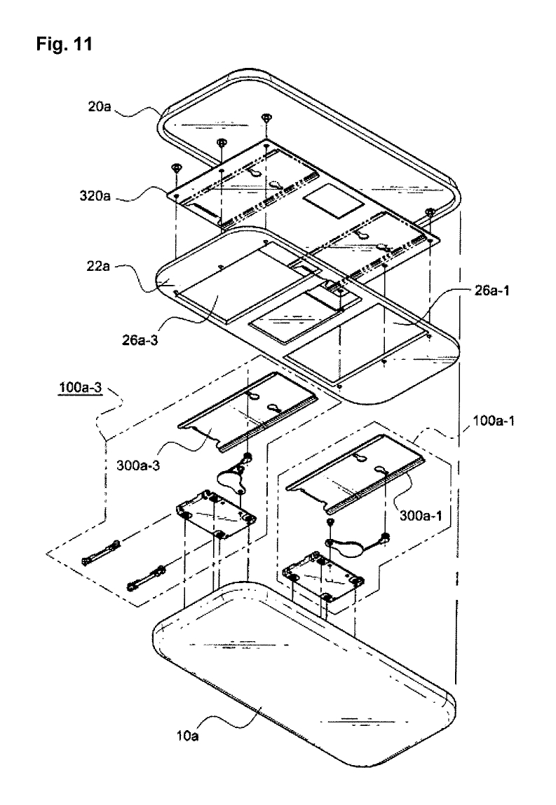

FIG. 10 is a perspective view of a dual sliding opening/closing apparatus according to a second embodiment of the present invention, and FIG. 11 is an exploded perspective of the apparatus shown in FIG. 10 when viewed in the opposite direction.

The construction of the pair of sliding opening/closing modules according to the second embodiment is the same as in the case of the first embodiment, except for the structure for coupling the guide rail members 300a-1 and 300a-3 of the pair of sliding opening/closing modules 100a-1 and 100a-3 to the second body 20a. In general, operation force for sliding (stress) acts on the coupling portions of the guide rail members 300a-1 and 300a-3 and the rear plate 22a. The rear plate 22a of the second body 20a, to which the guide rail members 300a-1 and 300a-3 are coupled, is generally made of a plastic material. This means that the coupling portions are likely to be damaged. Considering this, the second embodiment adopts a construction for increasing the coupling strength.

Particularly, in order to reinforce the strength of coupling between the guide rail members 300a-1 and 300a-3 and the second body 20a, the second embodiment proposes that the guide rail members 300a-1 and 300a-3 are coupled to a reinforcement plate 320a, and that through-holes 26a-1 and 26a-3 are formed on the rear plate 22a so that the pair of guide rail members 300a-1 and 300a-3 extend through. The reinforcement plate 320a and the rear plate 22a are successively stacked and coupled to the rear surface of the second body 20a so that the guide rail members 300a-1 and 300a-3 are coupled to the rear surface of the second body 20a. The reinforcement plate 320a is made of a metallic material having excellent strength, and is coupled to the guide rail members 300a-1 and 300a-3 by welding, bonding, or bolting, for example. As such, according to the second embodiment, the reinforcement plate 320a is added inside the rear plate 20a to increase the coupling strength of the guide rail members 300a-1 and 300a-3 and manufacture a durable electronic device that can be closed/opened by sliding movements.

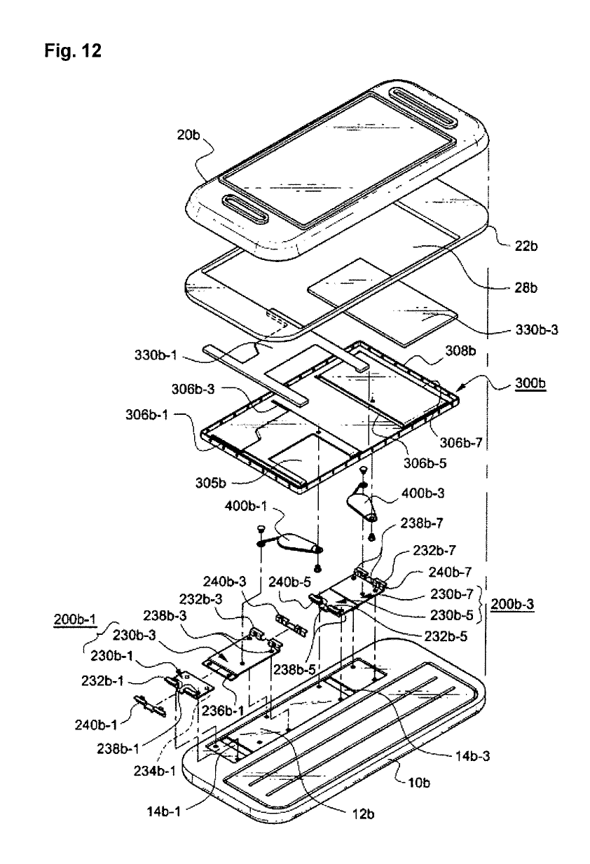

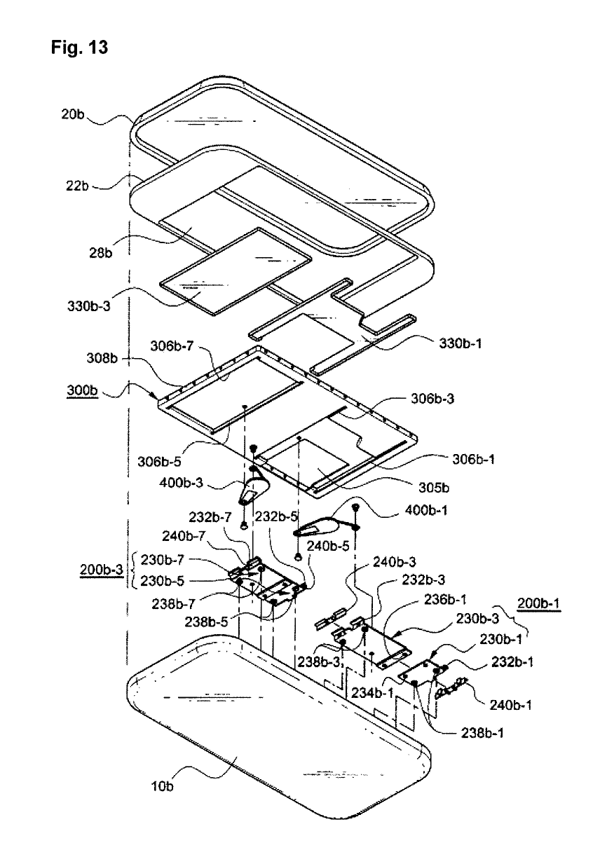

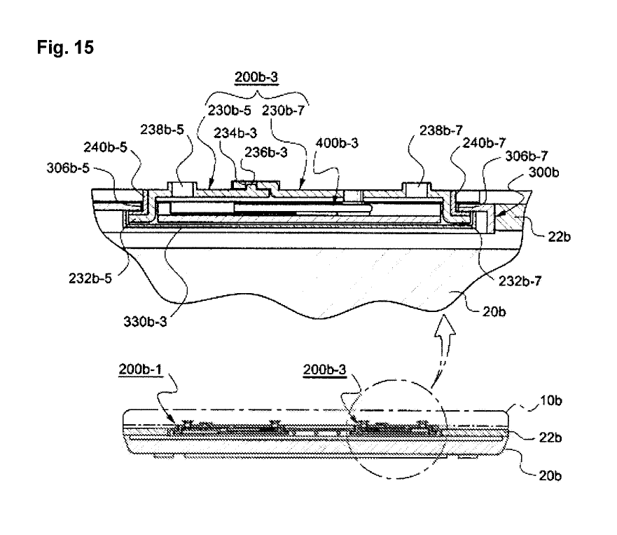

FIG. 12 is an exploded perspective view of a dual sliding opening/closing apparatus according to a third embodiment of the present invention. FIG. 13 is an exploded perspective view of the apparatus shown in FIG. 12 when viewed in the opposite direction. FIG. 14 is an assembled perspective view of the apparatus according to the third embodiment of the present invention. FIG. 15 is a sectional view of the apparatus shown in FIG. 14 taken along line B-B.

The third embodiment replaces the stepped rail portion according to the first and second embodiments with slot-type rail portions 306b-1, 306b-3, 306b-5, and 306b-7 formed on a guide rail member 300b (hereinafter, referred to as slot rail portions). Particularly, the guide rail member 300b consists of a single plate body, and has pairs of first and second slot rail portions 306b-1, 306b-3, 306b-5, and 306b-7 formed on the left and right sides, respectively. Both lateral peripheries of a pair of sliding members 200b-1 and 200b-3 are bent toward the slot rail portions 306b-1, 306b-3, 306b-5, and 306b-7 to form engaging portions 232b-1, 232b-3, 232b-5, and 232b-7. Respective sliding members 200b-1 and 200b-3 consist of two plate members 230b-1, 230b-3, 230b-5, and 230b-7, which overlap and couple to each other in between. Therefore, the pairs of engaging portions 232b-1, 232b-3, 232b-5, and 232b-7 on both sides of respective sliding members 200b-1 and 200b-3 are distributed on the lateral periphery of the double plate members 230b-1, 230b-3, 230b-5, and 230b-7, respectively. Respective ends of the engaging portions 232b-1, 232b-3, 232b-5, and 232b-7 are preferably bent outward in an L-shaped configuration. By integrating the double plate members 230b-1, 230b-3, 230b-5, and 230b-7 and constructing respective sliding members 200b-1 and 200b-3 in this manner, the engaging portions 232b-1, 232b-3, 232b-5, and 232b-7 of respective sliding members 200b-1 and 200b-3 can enter into the first and second slot rail portions 306b-1, 306b-3, 306b-5, and 306b-7. Coupling protrusions 234b-1 and 234b-3 and coupling holes 236b-1 and 236b-3 are formed on overlapping portions of the plate members 230b-1 and 230b-5 on one side and the plate members 230b-3 and 230b-7 on the other side, respectively, which are integrated into the sliding members 200b-1 and 200b-3, and are fitted to each other. Those skilled in the art can understand that, after assembling the springs 400b-1 and 400b-3 and the sliding members 200b-1 and 200b-3 to the guide rail members 300b-1 and 300b-3 and fixing the guide rail members 300b-1 and 300b 3 to the second body 20b, bolts are finally fastened to bolt holes 238b-1, 238b-3, 238b-5, and 238b-7 formed on the double plate members 230b-1, 230b-3, 230b-5, and 230b-7 of the first body 10b to combine and fix the sliding members 200b-1 and 200b-3. A single square recess 12b may be formed on the portion of the first body 10b, on which the sliding members 200b-1 and 200b-3 are mounted. Considering that the overlapping middle portions of the double plate members 230b-1, 230b-3, 230b-5, and 230b-7 of the sliding members 200b-1 and 200b-3 protrude a little, the square recess 12b preferably has receiving recesses 14b-1 and 14b-3 formed thereon to receive the protruding portions. Lubricating members 240b-1, 240b-3, 240b-5, and 240b-7 are mounted on the engaging portions 232b-1, 232b-3, 232b-5, and 232b-7 of the sliding members 200b-1 and 200b-3 to reduce friction occurring in portions contacting the slot rail portions 306b-1, 306b-3, 306b-5, and 306b-7 and facilitate the sliding. The contact surfaces of the engaging portions 232b-1, 232b-3, 232b-5, and 232b-7 may be covered with the lubricating members 240b-1, 240b-3, 240b-5, and 240b-7 in an insert type.

According to the present embodiment, a frame 308b extends along the periphery of the guide rail members 300b-1 and 300b-3 while being bent inward. The frame 308b is mounted inside a mounting unit 28b, which is formed on the rear surface of the second body 20b, and is fixedly fastened to it. Sealing plates 330b-1 and 330b-3 are mounted on the inner surface of the guide rail members 300b-1 and 300b-3, which is positioned inside the second body 20b while facing it. The two sealing plates 330b-1 and 330b-3 have a shape corresponding to that of the left and right slot rail portions 306b-1, 306b-3, 306b-5, and 306b-7, respectively, and completely surround them. As such, the sealing plates 330b-1 and 330b-3 prevent exposure of the interior of the second body 20b via the slot rail members 306b-1, 306b-3, 306b-5, and 306b-7, prevent alien substances from penetrating into the second body 20b, provide an aesthetic appearance, and reinforce the strength of the guide rail members 300b-1 and 300b-3.

The reason the left and right slot rail portions 306b-1, 306b-3, 306b-5, and 306b-7 of the guide rail members 300b-1 and 300b-3 have different shapes according to the present embodiment is to provide a hole 305b between the slot rail portions 306b-1 and 306b-3 on one side, through which a PCB cable can extend.

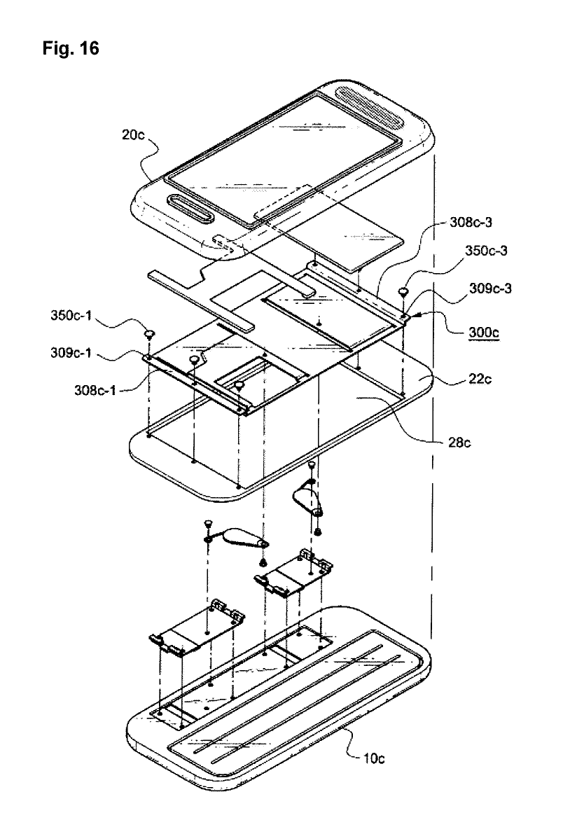

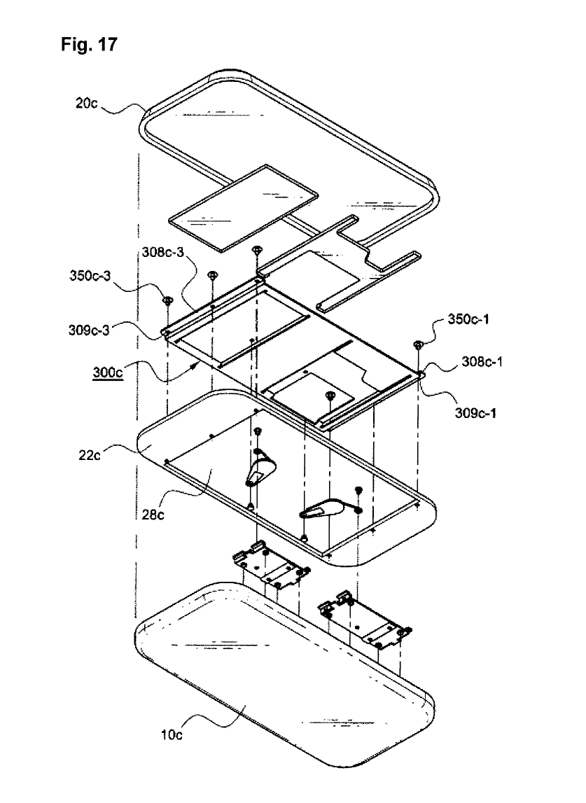

FIG. 16 is an exploded perspective view of a dual sliding opening/closing apparatus according to a fourth embodiment of the present invention, and FIG. 17 is an exploded perspective view of the apparatus shown in FIG. 16 when viewed in the opposite direction.

The fourth embodiment is an alternative to the third embodiment described above, and most components are identical to those according to the third embodiment, except for the coupling structure for the guide rail member 300c. Particularly, only both lateral peripheries (i.e. not all of the four peripheries) of the guide rail member 300c according to the fourth embodiment are bent twice toward the second body 20c to form bent portions 308c-1 and 308c-3, which have fastening holes 309c-1 and 309c-3 formed thereon so that, after fitting the guide rail member 300c to the mounting unit 28c of the rear plate 22c, bolts 305c-1 and 305c-3 are used to fix the guide rail member 300c to the rear plate 22c of the second body 20c. Other components are the same as has been described with reference to the third embodiment, and repeated description thereof will be omitted herein.

If necessary, the guide rail members according to the second to fourth embodiments of the present invention described above may be molded as an integral unit with the rear plate. In this case, the rear plate and the guide rail members are integrally fabricated by using the same material (e.g. metal or plastic). Preferably, in the case of the second embodiment, the guide rail members may be integrally molded on the reinforcement plate, which is integrated into the rear plate in an insert type. In the case of the third and fourth embodiments, the guide rail member is integrated into the rear plate in an insert type. Alternatively, slot rail portions are directly formed on the enclosed rear plate.

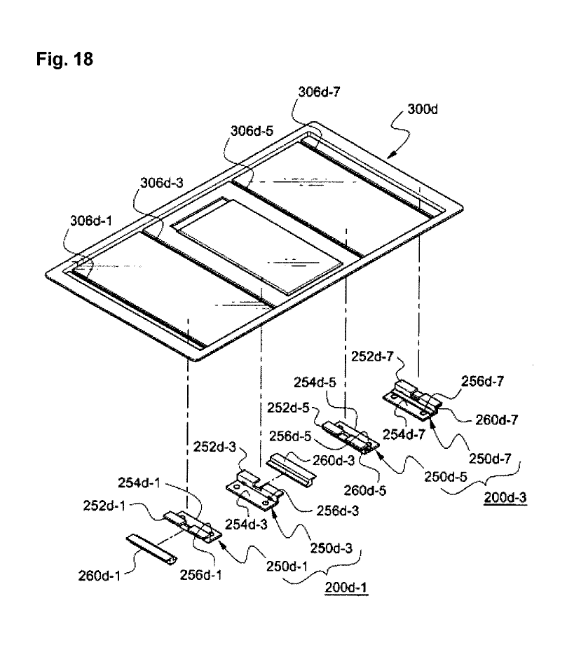

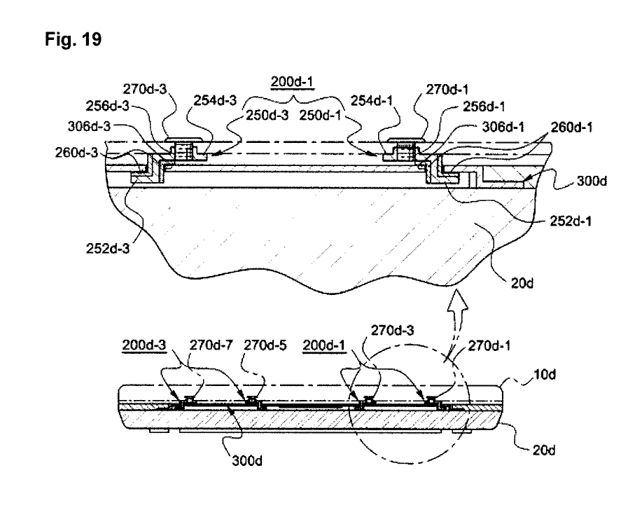

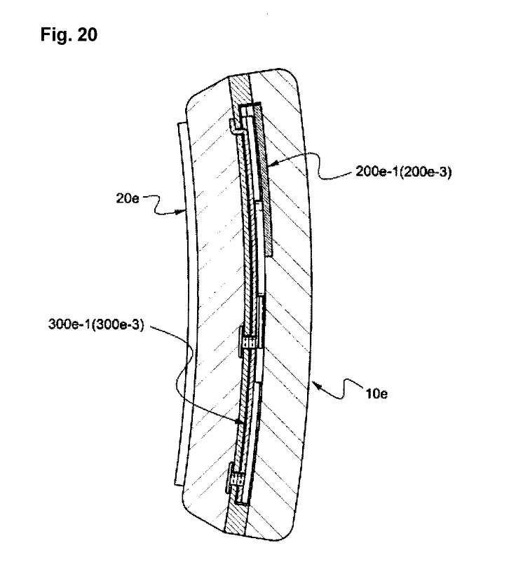

FIG. 18 is an exploded perspective view of a dual sliding opening/closing apparatus according to a fifth embodiment of the present invention. FIG. 19 is an assembled sectional view of the apparatus shown in FIG. 18. The present embodiment shows an example of modification of the structure for coupling the guide rail member and the sliding members (first and second bodies are omitted for clarity).

As shown, according to the fifth embodiment of the present invention, the guide rail member 300d and the sliding members 200d-1 and 200d-3 are coupled by forming pairs of slot rail portions 306d-1, 306d-3, 306d-5, and 306d-7 on the left and right sides of the guide rail member 300d made of a single plate body and then coupling the sliding members 200d-1 and 200d-3 including pairs of plate members 250d-1, 250d-3, 250d-5, and 250d-7 having engaging portions 252d-1, 252d-3, 252d-5, and 252d-7 to respective pairs of slot rail portions 306d-1, 306d-3, 306d-5, and 306d-7. Particularly, respective sliding members 200d-1 and 200d-3 consist of separate pairs of double plate members 250d-1, 250d-3, 250d-5, and 250d-7, which have fastening holes 256d-1, 256d-3, 256d-5, and 256d-7 formed on central plate portions 254d-1, 254d-3, 254d-5, and 254d-7, and engaging portions 252d-1, 252d-3, 252d-5, and 252d-7 bent outward from the central plate portions 254d-1, 254d-3, 254d-5, and 254d-7. In other words, engaging portions 252d-1, 252d-3, 252d-5, and 252d-7 are formed on the outside of the pairs of double plate members 250d-1, 250d-3, 250d-5, and 250d-7 in opposite directions, and fastening holes 256d-1, 256d-3, 256d-5, and 256d-7 are formed on the central plate portions 254d-1, 254d-3, 254d-5, and 254d-7. The engaging portions 252d-1, 252d-3, 252d-5, and 252d-7 are fitted to the slot rail portions 306d-1, 306d-3, 306d-5, and 306d-7, and the central plate portions 254d-1, 254d-3, 254d-5, and 254d-7 are forced against the first body 10d to fasten the bolts 270d-1 to 270d-7 to the fastening holes 256d-1, 256d-3, 256d-5, and 256d-7. This creates coupling between the guide rail member 300d and the sliding members 200d-1 and 200d-3, as well as between the sliding members 200d-1 and 200d-3 and the first body 10d.

Lubricating members 260d-1, 260d-3, 260d-5, and 260d-7 may also be mounted on portions of the engaging portions 252d-1, 252d-3, 252d-5, and 252d-7, which contact the guide rail member 300d, in an insert type.

FIG. 20 is an assembled sectional view of a dual sliding opening/closing apparatus according to a sixth embodiment of the present invention taken along the sliding direction.

The sliding opening/closing apparatus according to the present invention and the portable terminal based on it may be bent by a predetermined curvature along the sliding direction, as shown in FIG. 20. To this end, the first body 10e, the second body 20e, the sliding members 200e-1 and 200e-3, and the guide rail members 300e-1 and 300e-3 are bent by almost the same curvature, as shown in FIG. 20. The curvature of the first body 10e, etc. may be properly modified based on consideration of the usage of the terminal to guarantee its convenient use.

If necessary, the rear surface of the first body 10e and the front surface of the second body 20e may have a curvature different from that of portions contacting each other. Alternatively, the rear surface of the first body 10e and the front surface of the second body 20e are bent along straight lines or extend along a straight line as a whole, with only portions contacting each other and in-between components (e.g. sliding members, guide rail members) being bent. Although short components (e.g. springs) may have a predetermined curvature, they may also have no curvature.

Although several exemplary embodiments of the present invention have been described for illustrative purposes, those skilled in the art will appreciate that various modifications, additions and substitutions are possible, without departing from the scope and spirit of the invention as disclosed in the accompanying claims.

As mentioned above, the dual sliding opening/closing apparatus according to the present invention is advantageous in that, by mounting a pair of sliding modules on left and right sides of an electronic device, the device is prevented from vibrating in the leftward/rightward direction during upward/downward sliding movements. This improves the operational stability.

In other words, the inventive apparatus prevents leftward/rightward vibration during sliding movements, which would otherwise bend, wear, fracture, or break components that make contact during the movements. This improves the durability of the inventive apparatus and prolongs the service life of the electronic device equipped with the inventive apparatus.

The sliding opening/closing modules installed on the left and right sides of the electronic device balance both sides of the device and make the components compact and slim (therefore the entire device).

The sliding opening/closing apparatus according to the present invention, which has the above-mentioned advantages, is not easily bent by external force during sliding and guarantees smooth operation of the cover, etc. of the device.

What is claimed is:

1. A dual sliding opening/closing apparatus installed between first and second bodies so that the second body can slide between first and second positions on the first body, the apparatus comprising:
a plurality of sliding opening/closing modules having a sliding member installed on the first body in a sliding direction of the second body and a guide rail member movably coupled to the sliding member and installed on the second body, the sliding opening/closing modules being installed at two or more positions which are located along a direction perpendicular to the sliding direction so that, when the second body slides, the second body is prevented from vibrating in a leftward/rightward direction perpendicular to the sliding direction.

2. The apparatus as claimed in claim 1, wherein a pair of sliding opening/closing modules are installed on left and right sides of the first and second bodies.

3. A dual sliding opening/closing apparatus installed between first and second bodies so that the second body can slide between first and second positions on the first body, the apparatus comprising:
a pair of sliding members having engaging portions formed on both lateral peripheries in a sliding direction of the second body, the sliding members being installed on left and right sides of the first body which are located along a direction perpendicular to the sliding direction; and
a pair of guide rail members having rail portions on both lateral peripheries to engage with the engaging portions of the sliding members and slide, the guide rail members being installed in positions on the second body corresponding to the pair of sliding members, wherein
lubricating members are mounted on the engaging portions of the sliding members to reduce friction occurring in portions contacting the rail portions of the guide rail members and improve lubrication.

4. The apparatus as claimed in claim 3, wherein the engaging portions have a U-shaped configuration, and the rail portions are shaped to bend toward the engaging portions and fit into U-shaped portions.

5. The apparatus as claimed in claim 4, wherein the pair of guide rail members are directly coupled to left and right sides of a rear plate of the second body.

6. The apparatus as claimed in claim 4, wherein the apparatus further comprises a reinforcement plate coupled inside the rear plate of the second body, the pair of guide rail members are coupled to left and right slides of the reinforcement plate, through-holes are formed on portions of the rear plate corresponding to the guide rail members, and the pair of guide rail members are coupled to the first body via the through-holes of the rear plate.

7. The apparatus as claimed in claim 6, wherein the reinforcement plate is a metal plate.

8. A dual sliding opening/closing apparatus installed between first and second bodies so that the second body can slide between first and second positions on the first body, the apparatus comprising:
a pair of sliding members having engaging portions formed on both lateral peripheries in a sliding direction of the second body, the sliding members being installed on left and right sides of the first body which are located along a direction perpendicular to the sliding direction; and
a guide rail member provided with slot rail portions, the engaging portions of the pair of sliding members being fitted to the slot rail portions so as to slide, and installed on the second body, wherein
lubricating members are mounted on the engaging portions of the sliding members to reduce friction occurring in portions contacting the slot rail portions of the guide rail members and improve lubrication.

9. The apparatus as claimed in claim 8, wherein two plate members are overlapped in the middle and integrated into each sliding member, and outer peripheries of respective plate members are bent outward in an L-shaped configuration to form the engaging portions so that the engaging portions are fitted to the slot rail portions and coupled so as to move along the slot rail portions.

10. The apparatus as claimed in claim 9, wherein a coupling protrusion is formed on one of overlapping portions of the two plate members, and a coupling hole is formed on the other overlapping portion so that the coupling protrusion and the coupling hole are fitted and integrated into each other.

11. The apparatus as claimed in claim 10, wherein the two plate members are coupled by fastening bolts to bolt holes formed on the plate members from the first body after the coupling protrusion and the coupling hole have been integrated.

12. The apparatus as claimed in claim 8, wherein the sliding members comprise two separate plate members, and outer peripheries of respective plate members are bent outward in an L-shaped configuration to form the engaging portions so that, after being fitted to the slot rail portions, the engaging portions are coupled so as to move along the slot rail members by fastening bolts to bolt holes formed on the plate members from the first body.

13. The apparatus as claimed in claim 8, wherein peripheries on four sides of the guide rail member are bent vertically to form a frame, and a mounting unit is formed on a rear plate of the second body so that the frame of the guide rail member is inserted, mounted, and coupled to the mounting unit.

14. The apparatus as claimed in claim 8, wherein peripheries of both sides of the guide rail member are bent in an L-shaped configuration to form bent portions, a mounting unit is formed on a rear plate of the second body, the guide rail member is mounted on the mounting unit, and the bent portions are forced against and coupled to the rear plate.

15. The apparatus as claimed in claim 13, wherein sealing plates are mounted on a rear surface of the guide rail member to seal the slot rail portions.

16. The apparatus as claimed in claim 14, wherein sealing plates are mounted on a rear surface of the guide rail member to seal the slot rail portions.

17. The apparatus as claimed in claim 3, wherein the lubricating members are made of a plastic material having resistance to wear and lubrication properties, and are mounted on the engaging portions in an insert type.

18. The apparatus as claimed in claim 8, wherein the lubricating members are made of a plastic material having resistance to wear and lubrication properties, and are mounted on the engaging portions in an insert type.

19. The apparatus as claimed in claim 3, further comprising a spring installed between the sliding member and the guide rail member to push the sliding member and the guide rail member to the first or second position, the second body being closed in the first position and opened in the second position, respectively.

20. The apparatus as claimed in claim 8, further comprising a spring installed between the sliding member and the guide rail member to push the sliding member and the guide rail member to the first or second position, the second body being closed in the first position and opened in the second position, respectively.

21. The apparatus as claimed in claim 19, wherein the spring is a link-type spring comprising a coil portion having a first end coupled to and received in a link plate, and a leg portion extending from a second end of the coil portion and protruding from the link plate, and the link plate is rotatably installed on one of the sliding member and the guide rail member, and the leg portion is rotatably installed on the other of the sliding member and the guide rail member.

22. The apparatus as claimed in claim 20, wherein the spring is a link-type spring comprising a coil portion having a first end coupled to and received in a link plate, and a leg portion extending from a second end of the coil portion and protruding from the link plate, and the link plate is rotatably installed on one of the sliding member and the guide rail member, and the leg portion is rotatably installed on the other of the sliding member and the guide rail member.

23. The apparatus as claimed in claim 19, wherein the spring is a torsion spring comprising a coil portion and two leg portions extending from the coil portion, one of the leg portions is rotatably installed on one of the sliding member and the guide rail member, and the other leg is rotatably installed on the other of the sliding member and the guide rail member.

24. The apparatus as claimed in claim 20, wherein the spring is a torsion spring comprising a coil portion and two leg portions extending from the coil portion, one of the leg portions is rotatably installed on one of the sliding member and the guide rail member, and the other leg is rotatably installed on the other of the sliding member and the guide rail member.

25. The apparatus as claimed in claim 3, wherein the first body, the second body, the sliding member, and the guide rail member are bent along the sliding direction by an identical curvature.

26. The apparatus as claimed in claim 8, wherein the first body, the second body, the sliding member, and the guide rail member are bent along the sliding direction by an identical curvature.

27. The apparatus as claimed in claim 3, wherein a rear surface of the first body and a front surface of the second body are bent along straight lines or are straight as a whole, and contacting portions of the first and second bodies and the sliding member and the guide rail member in between are bent.

28. The apparatus as claimed in claim 8, wherein a rear surface of the first body and a front surface of the second body are bent along straight lines or are straight as a whole, and contacting portions of the first and second bodies and the sliding member and the guide rail member in between are bent.

29. The apparatus as claimed in claim 3, wherein the guide rail member is integrally molded on the rear plate of the second body.

30. The apparatus as claimed in claim 8, wherein the guide rail member is integrally molded on the rear plate of the second body.
